(19) United States
(12) Patent Application Publication
(10) Pub. No.: US 2008/0305406 A1
(43) Pub. Date: Dec. 11, 2008

(54) Photomask Blank, Photomask Manufacturing Method and Semiconductor Device Manufacturing Method

(75) Inventors: Atsushi Kominato, Yamanashi (JP); Takeyuki Yamada, Yamanashi (JP); Minoru Sakamoto, Yamanashi (JP); Masahiro Hashimoto, Yamanashi (JP)

Correspondence Address: SUGHRUE MION, PLLC, 2100 PENNSYLVANIA AVENUE, N.W., SUITE 800, WASHINGTON, DC, 20037, US

(73) Assignee: HOYA CORPORATION, Tokyo (JP)

(21) Appl. No.: 11/631,472

(22) PCT Filed: Jul. 8, 2005
(86) PCT No.: PCT/JP2005/012691

§ 371 Date: Jan. 4, 2007

(30) Foreign Application Priority Data
Jul. 9, 2004 (JP) 2004-202621

(51) Int. Cl. G03F 1/00; G03F 7/20

(52) U.S. Cl. 430/5; 430/319

(57) ABSTRACT

By increasing the dry etching rate of a light shielding film, the dry etching time can be shortened so that loss of a resist film is reduced. As a result, a reduction in thickness (to 300 nm or less) of the resist film becomes possible so that pattern resolution and pattern accuracy (CD accuracy) can be improved. Further, by shortening the dry etching time, a photomask blank and a photomask manufacturing method are provided, which can form a pattern of the light shielding film having an excellent sectional shape. In a photomask blank having a light shielding film on an optically transparent substrate, the photomask blank being a mask blank for a dry etching process adapted for a photomask producing method of patterning the light shielding film by the dry etching process using as a mask a pattern of a resist formed on the light shielding film, the light shielding film is made of a material having a selectivity exceeding 1 with respect to the resist in the dry etching process.

### TECHNICAL FIELD

This invention relates to a photomask blank and a photomask manufacturing method in which the dry etching rate of a light shielding film (an opaque film) is optimized for dry etching. Particularly, this invention relates to a photomask blank and a photomask manufacturing method, for manufacturing a photomask for use in an exposure apparatus using exposure light having a short wavelength of 200 nm or less as an exposure light source.

### BACKGROUND ART

Generally, in the semiconductor device manufacturing process, fine pattern formation is carried out by the use of the photolithography method. In this fine pattern formation, a number of substrates called photomasks are normally used. The photomask comprises, generally, an optically transparent glass substrate having thereon a light-shielding fine pattern made of a metal thin film or the like. The photolithography method is used also in the manufacture of the photomask.

In the manufacture of a photomask by the photolithography method, use is made of a photomask blank having a light shielding film on an optically transparent substrate such as a glass substrate. The manufacture of the photomask by the use of the photomask blank comprises an exposure process for performing required pattern exposure to a resist film formed on the photomask blank, a developing process for developing the resist film according to the required pattern exposure to form a resist pattern, an etching process for etching the light shielding film along the resist pattern, and a process for stripping and removing the remaining resist pattern. In the developing process, a developer is supplied after the required pattern exposure is performed to the resist film formed on the photomask blank so that a portion of the resist film soluble in the developer is dissolved so as to form the resist pattern. Further, in the etching process, using the resist pattern as a mask, an exposed portion of the light shielding film, where the resist pattern is not formed, is dissolved by dry etching or wet etching. Thus, a required mask pattern is formed on the optically transparent substrate. In this manner, the photomask is produced.

Upon miniaturization of a pattern of a semiconductor device, shortening of a wavelength of an exposure light source for use in the photolithography is required in addition to miniaturization of the mask pattern formed on the photomask. With respect to the exposure light source for use in the semiconductor device manufacture, the wavelength shortening has been advanced in recent years from a KrF excimer laser (wavelength 248 nm) to an ArF excimer laser (wavelength 193 nm) and further to an F2 excimer laser (wavelength 157 nm).

On the other hand, with respect to the photomask and photomask blank, miniaturization of the mask pattern formed on the photomask requires a reduction in thickness of the resist film in the photomask blank and the dry etching as a patterning technique in the photomask manufacture.

However, the reduction in thickness of the resist film and the dry etching are facing the following technical problems.

As one problem, upon advancing the reduction in thickness of the resist film of the photomask blank, the processing time of the light shielding film exists as one serious restriction. Chromium is generally used as a material of the light shielding film and a mixed gas of chlorine gas and oxygen gas is used as an etching gas in dry etching of chromium. When the light shielding film is patterned by dry etching using the resist pattern as a mask, since the resist is an organic film containing carbon as its main component, it is quite weak against an oxygen plasma forming a dry etching environment. During patterning the light shielding film by dry etching, it is necessary that the resist pattern formed on the light shielding film is left with a sufficient thickness. As one index, in order to make excellent the sectional shape of the mask pattern, the resist should have a thickness that still remains even when the etching time is about twice a just etching time (100% overetching). For example, since, in general, the etching selectivity of chromium as the material of the light shielding film to the resist film is 1 or less, the resist film requires a thickness twice or more the thickness of the light shielding film. As a method of shortening the processing time of the light shielding film, a reduction in thickness of the light shielding film is considered. The reduction in thickness of the light shielding film is proposed in Patent Document 1 noted below.

Patent Document 1 discloses that, in the photomask manufacture, the etching time can be shortened by reducing the thickness of a chromium light shielding film on a transparent substrate so that the shape of a chromium pattern is improved.

Patent Document 1: Japanese Unexamined Patent Application Publication (JP-A) No. H10-69055

### DISCLOSURE OF THE INVENTION

### Problem to be Solved by the Invention

However, if the thickness of the light shielding film is reduced, the light shielding property becomes insufficient. Therefore, even when pattern transfer is carried out by the use of such a photomask, a transfer pattern defect is caused to occur. The light shielding film requires a predetermined optical density (normally 3.0 or more) in order to sufficiently ensure its light shielding property. Therefore, even if the thickness of the light shielding film is reduced as in the foregoing Patent Document 1, a limit arises inevitably.

Therefore, this invention has been made for solving the conventional problems and has an object to, firstly, increase a dry etching rate of a light shielding film so as to shorten a dry etching time, thereby reducing loss of a resist film. As a result, a reduction in thickness (to 300 nm or less) of the resist film becomes possible so that the resolution and pattern accuracy (CD accuracy) can be improved. Further, the object is to provide a photomask blank and a photomask manufacturing method, which can form a pattern of a light shielding film having an excellent sectional shape by shortening a dry etching time.

Secondly, the object is to provide a photomask blank and a photomask manufacturing method, which can form a pattern of a light shielding film having an excellent sectional shape by a reduction in thickness of the light shielding film, while ensuring the light shielding performance necessary for the light shielding film by being used in an exposure apparatus using exposure light having a wavelength of 200 nm or less as an exposure light source.

Thirdly, the object is to provide a photomask blank and a photomask manufacturing method, which improve pattern accuracy of a light shielding film.

### Means for Solving the Problem

In order to solve the foregoing problems, this invention has the following structures.

(Structure 1) A photomask blank having a light shielding film on an optically transparent substrate, wherein the photomask blank is a mask blank for a dry etching process adapted for a photomask producing method of patterning the light shielding film by the dry etching process using as a mask a pattern of a resist formed on the light shielding film, and the light shielding film is made of a material having a selectivity exceeding 1 with respect to the resist in the dry etching process.

(Structure 2) A photomask blank having a light shielding film on an optically transparent substrate, wherein the photomask blank is a mask blank for a dry etching process adapted for a photomask producing method of patterning the light shielding film by the dry etching process using as a mask a pattern of a resist formed on the light shielding film, and the light shielding film is made of a material of which an etching rate is faster than a losing rate of the resist in the dry etching process.

(Structure 3) A photomask blank according to structure 1 or 2, wherein the resist film has a thickness of 300 nm or less.

(Structure 4) A photomask blank having a light shielding film on an optically transparent substrate, wherein the photomask blank is a mask blank for a dry etching process adapted for a photomask producing method of patterning at least the light shielding film by the dry etching process using as a mask a pattern of a resist formed on the light shielding film, and a dry etching rate of the light shielding film is set fast so that the resist remains on the light shielding film after patterning the light shielding film even when a thickness of the resist is set to 300 nm or less.

(Structure 5) A photomask blank according to any one of structures 1 to 4, wherein the light shielding film is made of a material containing chromium.

(Structure 6) A photomask blank according to any one of structures 2 to 5, wherein an amount of an additional element causing the dry etching rate of the light shielding film to be faster than the losing rate of the resist is controlled.

(Structure 7) A photomask blank having a light shielding film on an optically transparent substrate, wherein the photomask blank is a photomask blank for manufacturing a photomask for use in an exposure apparatus using exposure light having a wavelength of 200 nm or less as an exposure light source, the light shielding film is made of a material containing chromium and an additional element that causes a dry etching rate to be faster than chromium alone, and a thickness of the light shielding film is set so as to provide a required light shieldability.

(Structure 8) A photomask blank according to structure 6 or 7, wherein the additional element contained in the light shielding film is an element being at least one of oxygen and nitrogen.

(Structure 9) A photomask blank according to any one of structures 1 to 8, comprising a reflection preventing layer containing oxygen at a top layer portion of the light shielding film.

(Structure 10) A photomask blank according to structure 9, wherein the reflection preventing layer (the anti-reflective layer) further contains carbon.

(Structure 11) A photomask blank according to structure 9 or 10, wherein a ratio of the reflection preventing layer occupying in the whole of the light shielding film is set to 0.45 or less.

(Structure 12) A photomask blank according to any one of structures 1 to 11, wherein the dry etching process is performed in a plasma.

(Structure 13) A photomask blank according to any one of structures 1 to 12, wherein a dry etching gas for use in patterning the light shielding film is in the form of a chlorine-based gas or a mixed gas containing a chlorine-based gas and an oxygen gas.

(Structure 14) A photomask blank according to any one of structures 1 to 13, wherein the resist is a resist for electron-beam writing.

(Structure 15) A photomask blank according to any one of structures 1 to 14, wherein the resist is a chemically amplified resist.

(Structure 16) A photomask blank according to any one of structures 1 to 15, wherein a thickness of the light shielding film is set so that an optical density becomes 3.0 or more with respect to exposure light.

(Structure 17) A photomask blank according to structure 16, wherein:

the thickness of the light shielding film is 90 nm or less.

(Structure 18) A photomask blank according to any one of structures 1 to 15, wherein a halftone phase shifter film is formed between the optically transparent substrate and the light shielding film.

(Structure 19) A photomask blank according to structure 18, wherein the light shielding film is set such that a stack structure in combination with the halftone phase shifter film exhibits an optical density of 3.0 or more with respect to exposure light.

(Structure 20) A photomask blank according to structure 19, wherein a thickness of the light shielding film is 50 nm or less.

(Structure 21) A photomask manufacturing method comprising a step of patterning, by dry etching, the light shielding film in the photomask blank according to any one of structures 1 to 20.

(Structure 22) A photomask manufacturing method according to structure 21, comprising performing the dry etching under the conditions where when use is made, as the photomask blank, the photomask blank having the light shielding film made of the material containing at least oxygen in chromium and use is made, in the dry etching, the dry etching gas in the form of the mixed gas of the chlorine-based gas and the oxygen gas, the content of oxygen in the dry etching gas being reduced depending on the content of oxygen contained in the light shielding film of the photomask blank.

(Structure 23) A semiconductor device manufacturing method, comprising forming a circuit pattern on a semiconductor substrate by a photolithography method using a photomask obtained by the photomask manufacturing method according to structure 21 or 22.

As recited in Structure 1, the photomask blank of this invention is the photomask blank having the light shielding film on the optically transparent substrate, the photomask blank being the mask blank for the dry etching process adapted for the photomask manufacturing method of patterning the light shielding film by the dry etching process using as the mask the pattern of the resist formed on the light shielding film, wherein the light shielding film is made of the material having the selectivity exceeding 1 with respect to the resist in the dry etching process.

Since the light shielding film is made of the material having the selectivity exceeding 1 with respect to the resist in the dry etching process, the light shielding film is removed by dry etching faster than the resist in the dry etching process. Therefore, the thickness of the resist film required for patterning the light shielding film can be reduced so that the pattern accuracy (CD accuracy) of the light shielding film becomes excellent. Further, since the light shielding film is removed by dry etching faster than the resist, it is possible to form a pattern of the light shielding film having an excellent sectional shape by shortening of the dry etching time.

As recited in Structure 2, the photomask blank of this invention is the photomask blank having the light shielding film on the optically transparent substrate, the photomask blank being the mask blank for the dry etching process adapted for the photomask fabricating method of patterning the light shielding film by the dry etching process using as the mask the pattern of the resist formed on the light shielding film, wherein the light shielding film is made of the material of which the etching rate is faster than the losing rate of the resist in the dry etching process.

Since the light shielding film is made of the material of which the etching rate is faster than the etching rate of the resist in the dry etching process, the light shielding film is removed by dry etching faster than the resist in the dry etching process. Therefore, the thickness of the resist film required for patterning the light shielding film can be reduced so that the pattern accuracy (CD accuracy) of the light shielding film becomes excellent. Further, since the light shielding film is removed by dry etching faster than the resist, it is possible to form a pattern of the light shielding film having an excellent sectional shape by shortening of the dry etching time.

As recited in Structure 3, the thickness of the resist film can be set to 300 nm or less in Structure 1 or 2. By setting the thickness of the resist film to 300 nm or less, a change in CD shift amount with respect to the design size is reduced and therefore the CD linearity becomes excellent. The lower limit of the thickness of the resist film is preferably set such that the resist film remains when the light shielding film has been dry-etched using the resist pattern as the mask.

As recited in Structure 4, the photomask blank of this invention is the photomask blank having the light shielding film on the optically transparent substrate, the photomask blank being the mask blank for the dry etching process adapted for the photomask fabricating method of patterning at least the light shielding film by the dry etching process using as the mask the pattern of the resist formed on the light shielding film, wherein the dry etching rate of the light shielding film is set fast so that the resist remains on the light shielding film after patterning the light shielding film even when the thickness of the resist is set to 300 nm or less.

The dry etching rate of the light shielding film is controlled so that even if loss of the resist film occurs during the patterning of the light shielding film in the dry etching process, the resist film remains at the time of completion of the patterning of the light shielding film. Therefore, a required light shielding film pattern can be formed as designed. That is, the pattern accuracy of the light shielding film can be improved.

Further, by increasing the dry etching rate of the light shielding film, the loss of the resist film can be reduced. Therefore, the thickness of the resist film required for the patterning of the light shielding film can be reduced to 300 nm or less so that the pattern accuracy (CD accuracy) of the light shielding film becomes more excellent.

Moreover, by increasing the dry etching rate of the light shielding film, it is possible to form a pattern of the light shielding film having an excellent sectional shape by shortening of the dry etching time.

As recited in Structure 5, in this invention, the light shielding film is preferably made of the material containing chromium.

As recited in Structure 6, by adding the additional element, which increases the dry etching rate, in the light shielding film and controlling the content of the additional element so as to cause the dry etching rate of the light shielding film to be faster than the dry etching rate (losing rate) of the resist, the effect of this invention is easily obtained, which is thus preferable.

As recited in Structure 7, the photomask blank of this invention is the photomask blank having the light shielding film on the optically transparent substrate, the photomask blank being the photomask blank for manufacturing the photomask for use in the exposure apparatus using the exposure light having the wavelength of 200 nm or less as the exposure light source, wherein the light shielding film is made of the material containing chromium and the additional element that causes the dry etching rate to be faster than chromium alone and the thickness of the light shielding film is set so as to provide the required light shielding property.

In this invention, as different from the conventional idea of minimizing the thickness of the light shielding film, the dry etching time can be shortened by changing a material of the light shielding film to a material of which the dry etching rate is faster. On the other hand, since the material whose dry etching rate is faster has a small adsorption coefficient at a wavelength of i-line (365 nm) or KrF excimer laser (248 nm) conventionally used in an exposure apparatus, it is necessary to increase the thickness thereof in order to obtain the required optical density. Therefore, shortening of the dry etching time cannot be expected. The present inventor has found that even the material whose etching rate is faster has an adsorption coefficient of a certain degree at the exposure wavelength of 200 nm or less, for example, the exposure wavelength of ArF excimer laser (193 nm) or F2 excimer laser (157 nm) and, therefore, the required optical density can be obtained with a certain thin film without particularly increasing the thickness thereof.

Specifically, this invention relates to the photomask blank for manufacturing the photomask for use in the exposure apparatus using the exposure light having the wavelength of 200 nm or less as the exposure light source. The light shielding film is the certain thin film made of the material whose dry etching rate is fast in order to achieve shortening of the dry etching time. By this shortening of the dry etching time, it is possible to form a pattern of the light shielding film having the excellent sectional shape.

In this invention, the light shielding film is made of the material containing chromium and the additional element that causes the dry etching rate to be faster than chromium alone.

As recited in Structure 8, the additional element contained in the light shielding film to increase the dry etching rate in the foregoing Structure 6 or 7 is the element being at least one of oxygen and nitrogen. The dry etching rate of the light shielding film made of the material containing chromium and such an additional element becomes faster than that of a light shielding film made of chromium alone so that it is possible to achieve shortening of the dry etching time. Further, the light shielding film made of such a chromium-based material can obtain the required optical density even in the form of the certain thin film without particularly increasing the thickness thereof.

As recited in Structure 9, the light shielding film can comprise the reflection preventing layer containing oxygen. With such a reflection preventing layer, the reflectance at the exposure wavelength can be suppressed to a low value. Therefore, it is possible to reduce the influence of standing wave upon using a photomask. Further, since it is possible to suppress the reflectance to a low value with respect to a wavelength (e.g. 257 nm, 364 nm, 488 nm, or the like) used in a defect inspection of a photomask blank or photomask, the accuracy of detecting a defect is improved.

As recited in Structure 10, by further containing carbon in the reflection preventing layer, the reflectance particularly to the inspection wavelength for use in the defect inspection can be further reduced. It is preferable to contain carbon in the reflection preventing layer to a degree such that the reflectance to the inspection wavelength becomes 20% or less.

Since the dry etching rate tends to be reduced when carbon is contained in the reflection preventing layer, it is preferable to set the ratio of the reflection preventing layer occupying in the whole light shielding film to 0.45 or less as recited in Structure 11 in order to demonstrate the effect of this invention to the maximum.

As recited in Structure 12, the light shielding film of this invention particularly exhibits the effect when the dry etching process is carried out in the plasma, i.e. in an environment where the resist film is exposed to the plasma so as to be reduced in amount.

As recited in Structure 13, as a dry etching gas for use in patterning the light shielding film, it is preferable for this invention to use the dry etching gas in the form of the chlorine-based gas or the mixed gas containing the chlorine-based gas and the oxygen gas. With respect to the light shielding film made of the material containing the elements such as chromium, oxygen and/or nitrogen in this invention, it is possible to achieve shortening of the dry etching time by performing dry etching by the use of the foregoing dry etching gas.

As recited in Structure 14, by using the resist for electron-beam writing as the resist for use in this invention, it becomes possible to reduce the thickness of the resist film so that the pattern accuracy (CD accuracy) of the light shielding film can be preferably improved.

As recited in Structure 15, the resist is preferably the chemically amplified resist. By using the chemically amplified resist as the resist formed on the light shielding film, high resolution is obtained. Therefore, it is possible to sufficiently cope with a use that requires a fine pattern such as a 65 nm node or 45 nm node according to the semiconductor design rule. Further, since the chemically amplified resist is better in dry etching resistance as compared with a polymer resist, the thickness of the resist film can be further reduced. Therefore, the CD linearity is improved.

As recited in Structure 16, in the photomask blank for the binary mask, the thickness of the light shielding film is set so that the optical density becomes 3.0 or more with respect to the exposure light. Specifically, as recited in Structure 17, it is preferable for this invention that the thickness of the light shielding film is 90 nm or less. By setting the thickness of the light shielding film to 90 nm or less, it is possible to reduce the line width error caused by the global loading phenomenon and microloading phenomenon (phenomenon where the etching rate of a fine-pattern portion is reduced as compared with that of a large-pattern portion) upon dry etching. Further, the light shielding film in this invention can obtain the required optical density at the exposure wavelength of 200 nm or less even when the thickness thereof is reduced to 90 nm or less. There is no particular limitation to the lower limit of the thickness of the light shielding film. The thickness of the light shielding film can be reduced as long as the required optical density can be obtained.

As recited in Structure 18, the halftone phase shifter film may be formed between the optically transparent substrate and the light shielding film. In this case, as recited in Structure 19, the light shielding film is set such that the stack structure in combination with the halftone phase shifter film exhibits the optical density of 3.0 or more with respect to the exposure light. Specifically, as recited in Structure 20, the thickness of the light shielding film can be set to 50 nm or less. Therefore, by setting the thickness of the light shielding film to 50 nm or less, it is possible to further reduce the line width error caused by the global loading phenomenon and microloading phenomenon (phenomenon where the etching rate of a fine-pattern portion is reduced as compared with that of a large-pattern portion) upon dry etching like in the foregoing.

As recited in Structure 21, according to the photomask manufacturing method comprising the step of patterning, by dry etching, the light shielding film in the photomask blank as recited in any of Structures 1 to 17, the dry etching time can be shortened so that it is possible to obtain a photomask in which the light shielding film pattern having the excellent sectional shape is accurately formed.

As recited in Structure 22, by performing the dry etching under the conditions where when use is made, as the photomask blank, the photomask blank having the light shielding film made of the material containing at least oxygen in chromium and use is made, in the dry etching, the dry etching gas in the form of the mixed gas of the chlorine-based gas and the oxygen gas, the content of oxygen in the dry etching gas is reduced depending on the content of oxygen contained in the light shielding film of the photomask blank, it is possible to prevent damage to the resist pattern during dry etching. As a consequence, the photomask with improved pattern accuracy of the light shielding film is obtained.

Most generally, dry etching of a light shielding film made of a chromium-based material is carried out by using a chlorine-based gas to produce chromyl chloride (CrCl₂O₂). Therefore, an etching gas basically requires oxygen and use is normally made of a dry etching gas in the form of a mixture of a chlorine-based gas and an oxygen gas. However, oxygen in the etching gas is known to give damage to a resist pattern and thus adversely affects pattern accuracy of a light shielding film to be formed. Accordingly, in the case of using the photomask blank having the light shielding film made of the material containing at least oxygen in chromium, since chromyl chloride is produced by reaction of oxygen and chromium in the light shielding film with the chlorine-based gas, the amount of oxygen in the dry etching gas can be reduced or set to zero. As a result, since the amount of oxygen that adversely affects the resist pattern can be reduced, the pattern accuracy of the light shielding film formed by dry etching is improved. Therefore, it becomes possible to obtain a photomask in which a fine pattern of particularly a submicron-level pattern size is formed with high accuracy.

As recited in Structure 23, by the use of the photomask obtained by Structure 21 or 22, the semiconductor device having the circuit pattern with excellent pattern accuracy which is formed on the semiconductor substrate by the photolithography method is obtained.

### EFFECT OF THE INVENTION

According to this invention, by increasing the dry etching rate of a light shielding film, the dry etching time can be shortened so that it is possible to reduce loss of a resist film. As a result, a reduction in thickness (to 300 nm or less) of the resist film becomes possible so that pattern resolution and pattern accuracy (CD accuracy) can be improved. Further, by shortening the dry etching time, it is possible to provide a photomask blank that can form a light shielding film pattern having an excellent sectional shape. Further, according to this invention, it is possible to provide a photomask blank and a photomask manufacturing method, which can form a pattern of a light shielding film having an excellent sectional shape by a reduction in thickness of the light shielding film, while ensuring the light shielding performance necessary for the light shielding film by being used in an exposure apparatus using exposure light having a wavelength of 200 nm or less as an exposure light source.

Further, according to this invention, it is possible to provide a photomask blank and a photomask manufacturing method, which prevent damage to a resist pattern during dry etching to thereby improve pattern accuracy of a light shielding film.

Moreover, according to this invention, a semiconductor device having a circuit pattern with excellent pattern accuracy formed on a semiconductor substrate by the photolithography method is obtained using a photomask obtained by this invention.

### BEST MODE FOR CARRYING OUT THE INVENTION

Hereinbelow, embodiments of this invention will be described in detail with reference to the drawings.

FIG. 1 is a sectional view showing a first embodiment of a photomask blank of this invention.

A photomask blank 10 of FIG. 1 is in the form having a light shielding film 2 on an optically transparent substrate 1. Herein, a glass substrate is generally used as the optically transparent substrate 1. Since the glass substrate is excellent in flatness and smoothness, when pattern transfer onto a semiconductor substrate is performed by the use of a photomask, highly accurate pattern transfer can be carried out without causing strain or the like of a transfer pattern.

The thickness of a resist film and the dry etching rate of the light shielding film 2 are controlled so that even if loss of the resist film occurs during patterning of the light shielding film 2 by dry etching using as a mask a resist pattern formed thereon, the resist film still remains at the time of completion of the patterning of the light shielding film. The light shielding film 2 is, specifically, made of a material containing chromium and an additional element/elements that increase the dry etching rate as compared with chromium alone. The material preferably contains at least oxygen and/or nitrogen as the additional element/elements that increase the dry etching rate as compared with chromium alone. When oxygen is contained in the light shielding film 2, the content of oxygen is preferably in the range of 5 to 80 atm %. When the content of oxygen is less than 5 atm %, it is difficult to obtain the effect that the dry etching rate is made faster than chromium alone. On the other hand, when the content of oxygen exceeds 80 atm %, the absorption coefficient at a wavelength of 200 nm or less, for example, that of an ArF excimer laser (wavelength 193 nm) is reduced. Therefore, it becomes necessary to increase the thickness of the film in order to obtain the required optical density. In view of reducing the amount of oxygen in a dry etching gas, it is preferable that the content of oxygen in the light shielding film 2 is set, particularly, in the range of 60 to 80 atm %.

On the other hand, when nitrogen is contained in the light shielding film 2, the content of nitrogen is preferably in the range of 20 to 80 atm %. When the content of nitrogen is less than 20 atm %, it is difficult to obtain the effect that the dry etching rate is made faster than chromium alone. On the other hand, when the content of nitrogen exceeds 80 atm %, the absorption coefficient at a wavelength of 200 nm or less, for example, that of the ArF excimer laser (wavelength 193 nm) is reduced. Therefore, it becomes necessary to increase the thickness of the film in order to obtain the required optical density.

Both oxygen and nitrogen may be contained in the light shielding film 2. In this case, the total content of oxygen and nitrogen is preferably set in the range of 10 to 80 atm %. When both oxygen and nitrogen are contained in the light shielding film 2, the content ratio of oxygen and nitrogen is not particularly limited but is properly determined in consideration of the adsorption coefficient and so on.

The light shielding film 2 containing oxygen and/or nitrogen may further contain an element such as carbon or hydrogen.

It is not necessary that a method of forming the light shielding film 2 be particularly limited, but nevertheless, a sputtering film forming method is in particular preferably used. Since a uniform film with a constant thickness can be formed according to the sputtering film forming method, it is suitable for this invention. When the light shielding film 2 is deposited on the optically transparent substrate 1 by the sputtering film forming method, a chromium (Cr) target is used as a sputtering target and, as a sputtering gas introduced into a chamber, use is made of a gas obtained by mixing a gas such as oxygen, nitrogen, or carbon dioxide into an argon gas. When use is made of the sputtering gas obtained by mixing the oxygen gas or carbon dioxide gas into the argon gas, it is possible to form a light shielding film containing oxygen in chromium. When use is made of the sputtering gas obtained by mixing the nitrogen gas into the argon gas, it is possible to form a light shielding film containing nitrogen in chromium.

The thickness of the light shielding film 2 is preferably 90 nm or less. The reason is that, in order to cope with pattern miniaturization to the submicron-level pattern size in recent years, it is considered that when the thickness of the film exceeds 90 nm, it becomes difficult to form a fine pattern due to the pattern microloading phenomenon and so on at the time of dry etching. By reducing the thickness of the film to a certain degree, a reduction in aspect ratio of a pattern (the ratio of a pattern depth to a pattern width) can be achieved. Therefore, it is possible to reduce the line width error caused by the global loading phenomenon and microloading phenomenon. Further, by reducing the thickness of the film to a certain degree, it becomes possible to prevent damage (collapse or the like) to a pattern, particularly a pattern having a submicron-level pattern size. The light shielding film 2 in this invention can obtain a required optical density (normally 3.0 or more) at an exposure wavelength of 200 nm or less even when the thickness of the film is reduced to 90 nm or less. There is no lower limit of the thickness of the light shielding film 2 as long as the required optical density can be obtained.

Further, the light shielding film 2 is not limited to a single layer but may be in the form of multilayers where each layer preferably contains oxygen and/or nitrogen. For example, the light shielding film 2 may include a reflection preventing layer at a surface layer portion (top layer portion). In this case, as the reflection preventing layer, a material of, for example, CrO, CrCO, CrNO, or CrCON is preferably used. In order to reduce the influence of standing wave upon using a photomask, it is preferable to suppress the reflectance at the exposure wavelength to, for example, 20% or less, and preferably 15% or less by providing the reflection preventing layer. Further, in order to detect a defect with high accuracy, it is preferable to suppress the reflectance to, for example, 30% or less with respect to a wavelength (e.g. 257 nm, 364 nm, 488 nm, or the like) used in a defect inspection of a photomask blank or photomask. Particularly, by using a film containing carbon as the reflection preventing layer, the reflectance to the exposure wavelength can be reduced and further the reflectance to the foregoing inspection wavelength (particularly 257 nm) can be reduced to 20% or less, which is thus preferable. Specifically, the content of carbon is preferably set to 5 to 20 atm %. When the content of carbon is less than 5 atm %, the effect of reducing the reflectance is reduced. On the other hand, when the content of carbon exceeds 20 atm %, the dry etching rate is reduced to increase a dry etching time required for patterning the light shielding film by dry etching. This makes it difficult to reduce the thickness of the resist film and therefore, is not preferable. Since, however, the dry etching rate tends to be reduced when carbon is contained in the reflection preventing layer, it is preferable to set the ratio of the reflection preventing layer occupying in the whole light shielding film to 0.45 or less, more preferably 0.30 or less, and further preferably 0.20 or less in order to demonstrate the effect of this invention to the maximum. The reflection preventing layer may also be provided on the back surface (glass surface) side. Further, the light shielding film 2 may be formed as a composition gradient film in which the reflection preventing layer at the surface layer portion and the other layer/layers form a stepwise or continuous gradient in composition.

On the other hand, a chromium-free reflection preventing film may be provided on the light shielding film 2. As such a reflection preventing film, a material of, for example, SiO₂, SiON, MSiO, or MSiON (M is a chromium-free metal such as molybdenum) is used.

As shown in FIG. 2, (a) which will be referred to later, the photomask blank may be in the form where a resist film 3 is formed on the light shielding film 2. The thickness of the resist film 3 is preferably as thin as possible in order to make excellent the pattern accuracy (CD accuracy) of the light shielding film. Specifically, in the case of the photomask blank for a so-called binary mask like in this embodiment, the thickness of the resist film 3 is preferably set to 300 nm or less, more preferably 200 nm or less, and further preferably 150 nm or less. The lower limit of the thickness of the resist film is set such that the resist film remains when the light shielding film has been dry-etched using a resist pattern as a mask. In order to obtain a high resolution, a material of the resist film 3 is preferably a chemically amplified resist having high resist sensitivity. The chemically amplified resist is better in dry etching resistance as compared with a polymer resist having been generally used in EB writing. Thus, the thickness of the resist film can be further reduced. Therefore, the CD linearity is improved. Further, the average molecular weight of the polymer resist is 100,000 or more and the resist having such a large molecular weight generally exhibits a large ratio of a reduction in molecular weight during dry etching. Therefore, the dry etching resistance thereof is poor. Accordingly, it is preferable to use a resist having an average molecular weight of less than 100,000 and preferably less than 50,000 because the dry etching resistance can be improved.

Further, the light shielding film of this invention is made of a material having a selectivity exceeding 1 with respect to the resist in the dry etching process. The selectivity is given by a ratio of a loss amount of the resist and a loss amount of the light shielding film (=light shielding film loss amount/resist loss amount) with respect to the dry etching process. In view of preventing degradation of the sectional shape of the light shielding film pattern and suppressing the global loading phenomenon, the selectivity of the light shielding film to the resist is preferably set to greater than 1 and less than or equal to 10, and more preferably greater than 1 and less than or equal to 5.

Likewise, the light shielding film of this invention is made of a material whose etching rate is faster than the losing rate of the resist in the dry etching process. In view of preventing degradation of the sectional shape of the light shielding film pattern and suppressing the global loading phenomenon, the ratio of the losing rate of the resist and the etching rate of the light shielding film (resist losing rate: light shielding film etching rate) is preferably set to greater than 1:1 and less than or equal to 1:10, and more preferably greater than 1:1 and less than or equal to 1:5.

Now, description will be made about a photomask manufacturing method using the photomask blank 10 shown in FIG. 1.

The photomask manufacturing method using the photomask blank 10 comprises a process for patterning the light shielding film 2 of the photomask blank 10 by dry etching and, specifically, comprises an exposure process for applying required pattern exposure to a resist film formed on the photomask blank 10, a developing process for developing the resist film according to the required pattern exposure to form a resist pattern, an etching process for etching the light shielding film along the resist pattern, and a process for peeling off and removing the remaining resist pattern.

FIG. 2 is a sectional view showing in sequence the photomask manufacturing processes using the photomask blank 10.

FIG. 2, (a) shows the state where the resist film 3 is formed on the light shielding film 2 of the photomask blank 10 of FIG. 1. As a resist material, use can be made of either a positive resist material or a negative resist material.

Then, FIG. 2, (b) shows the exposure process for applying required pattern exposure to the resist film 3 formed on the photomask blank 10. The pattern exposure is carried out by the use of an electron-beam writing apparatus, a laser writing apparatus, or the like. As the foregoing resist material, use is made of a material having photosensitivity adapted to an electron or laser beam.

Then, FIG. 2, (c) shows the developing process for developing the resist film 3 according to the required pattern exposure to form a resist pattern 3a. In the developing process, a developer is supplied after the required pattern exposure is applied to the resist film 3 formed on the photomask blank 10, and a portion of the resist film soluble in the developer is dissolved so as to form the resist pattern 3a.

Successively, FIG. 2, (d) shows the etching process for etching the light shielding film 2 along the resist pattern 3a. In this invention, it is preferable to use dry etching. In the etching process, using the resist pattern 3a as a mask, an exposed portion of the light shielding film 2, where the resist pattern 3a is not formed, is dissolved by dry etching. Thus, a required light shielding film pattern 2a (mask pattern) is formed on the optically transparent substrate 1.

In this dry etching, it is preferable for this invention to use a dry etching gas in the form of a chlorine-based gas or a mixed gas containing a chlorine-based gas and an oxygen gas. With respect to the light shielding film 2 made of the material containing the elements such as chromium, oxygen and/or nitrogen, etc. in this invention, by performing dry etching using the foregoing dry etching gas, it is possible to increase the dry etching rate, shorten the dry etching time, and form the light shielding film pattern having the excellent sectional shape. As the chlorine-based gas for use in the dry etching gas, for example, Cl₂, SiCl₄, HCl, CCl₄, CHCl₃, or the like are used.

In the case of the light shielding film made of the material containing at least oxygen in chromium, chromyl chloride is produced by reaction of oxygen and chromium in the light shielding film with the chlorine-based gas. Therefore, when using the dry etching gas in the form of the mixed gas containing the chlorine-based gas and the oxygen gas in dry etching, the content of oxygen in the dry etching gas can be reduced depending on the content of oxygen contained in the light shielding film. By performing dry etching using the dry etching gas with the content of oxygen reduced as described above, the amount of oxygen that adversely affects the resist pattern can be reduced to thereby prevent damage to the resist pattern during dry etching. As a consequence, a photomask with improved pattern accuracy of the light shielding film is obtained. Depending on the content of oxygen contained in the light shielding film, it is possible to use a dry etching gas with the amount of oxygen in the dry etching gas being zero, i.e. containing no oxygen.

FIG. 2, (e) shows a photomask 20 obtained by peeling off and removing the remaining resist pattern 3a. In this manner, the photomask, in which the light shielding film pattern having the excellent sectional shape is accurately formed, is obtained.

This invention is not limited to the embodiment as described above. That is, not limited to the photomask blank for the so-called binary mask having the light shielding film formed on the optically transparent substrate, it may also be a photomask blank for use in manufacturing, for example, a halftone phase shift mask or a Levenson phase shift mask. In this case, as shown in a later-described second embodiment, a light shielding film is formed on a halftone phase shift film on an optically transparent substrate. In this structure, since it is sufficient that a required optical density (preferably 3.0 or more) is obtained by a combination of the halftone phase shift mask and the light shielding film, the optical density of the light shielding film itself can be set to a value, for example, smaller than 3.0.

Now, the second embodiment of a photomask blank of this invention will be described with reference to FIG. 4, (a).

A photomask blank 30 of FIG. 4, (a) is in the form having a halftone phase shifter film 4 on an optically transparent substrate 1 and a light shielding film 2 composed of a shielding layer 5 and a reflection preventing layer 6 on the halftone phase shifter film 4. Since the optically transparent substrate 1 and the light shielding film 2 have been described in the foregoing first embodiment, description thereof is omitted.

The halftone phase shifter film 4 transmits light having an intensity that does not substantially contribute to exposure (e.g. 1% to 20% with respect to an exposure wavelength) and has a predetermined phase difference. By the use of a light semi-transmissive portion in the form of the patterned halftone phase shifter film 4 and a light transmissive portion, where the halftone phase shifter film 4 is not formed, which transmits light having an intensity that substantially contributes to the exposure, the halftone phase shifter film 4 provides a relationship where the phase of the light transmitted through the light semi-transmissive portion is substantially inverted with respect to the phase of the light transmitted through the light transmissive portion. Thus, the lights transmitted through the neighborhood of a boundary portion between the light semi-transmissive portion and the light transmissive portion and bending into the others' regions by a diffraction phenomenon are canceled each other. Thereby, the light intensity at the boundary portion is adjusted to be zero so as to improve the contrast, i.e. the resolution, at the boundary portion.

The halftone phase shifter film 4 is preferably made of a material having etching characteristics different from those of the light shielding film 2 formed thereon. For example, as the halftone phase shifter film 4, use is made of a material containing, as main components, metal such as molybdenum, tungsten, or tantalum, silicon, and oxygen and/or nitrogen. The halftone phase shifter film 4 may be in the form of a single layer or a plurality of layers.

In this second embodiment, the light shielding film 2 is set such that the stack structure in the form of a combination of the halftone phase shifter film and the light shielding film exhibits an optical density of 3.0 or more with respect to the exposure light. The thickness of the light shielding film 2 thus set is preferably 50 nm or less. The reason is that, like in the foregoing first embodiment, it is considered that it becomes difficult to form a fine pattern due to the pattern microloading phenomenon and so on upon dry etching. Further, in this embodiment, the thickness of a resist film formed on the foregoing reflection preventing layer 6 is preferably 250 nm or less, more preferably 200 nm or less, and further preferably 150 nm or less. The lower limit of the thickness of the resist film is set such that the resist film remains when the light shielding film has been dry-etched using a resist pattern as a mask. Moreover, like in the foregoing embodiment, a material of the resist film is preferably a chemically amplified resist having high resist sensitivity in order to obtain a high resolution.

Hereinbelow, the embodiments of this invention will be described in further detail in terms of examples. Description will also be made about a comparative example in contrast to the examples.

### EXAMPLES 1 TO 10, COMPARATIVE EXAMPLE 1

A light shielding film was formed on a quartz glass substrate by the use of a single wafer sputtering apparatus. A chromium target was used as a sputtering target. Composition of a sputtering gas was changed as shown by the gas flow rate ratios in Table 1. In this manner, photomask blanks (Examples 1 to 10, Comparative Example 1) having light shielding films of different compositions were obtained, respectively. The compositions of the light shielding films of the obtained photomask blanks are as shown in Table 1. The thickness of each light shielding film is also shown in Table 1, and was set to a value in which the optical density (OD) became 3.0 at a wavelength of 193 nm.

Then, an electron-beam resist film (CAR-FEP171 manufactured by Fuji Film Arch (FFA)) as a chemically amplified resist was formed on each photomask blank. The resist film was formed by spin coating by the use of a spinner (spin coating apparatus). After coating the resist film, a predetermined heated-air drying treatment was carried out by the use of a heated-air dryer.

Subsequently, required pattern writing was carried out with respect to the resist film formed on each photomask blank by the use of an electron-beam writing apparatus. Thereafter, developing was carried out by the use of a predetermined developer to thereby form a resist pattern.

Then, dry etching of the light shielding film was performed along the resist pattern formed on each photomask blank. As a dry etching gas, use was made of a mixed gas of Cl₂ and O₂ (Cl₂:O₂=4:1). A just etching time (time required for etching to reach the substrate) in each dry etching is shown in Table 1.

TABLE 1

| | | | | | | | | | | | Etching |
|---|---|---|---|---|---|---|---|---|---|---|---|
| | Gas Flow Rate Ratio (%) | | | | Element Ratio (%) | | | | Thickness | Etching Time | Rate |
| | Ar | N₂ | O₂ | CO₂ | Cr | N | O | C | (Å) (*) | (sec) (**) | (Å/sec) |
| Example 1 | 93 | | 7 | | 92 | 0 | 8 | 0 | 531 | 240 | 2.2 |
| Example 2 | 73 | | 27 | | 40 | 0 | 60 | 0 | 772 | 231 | 3.3 |
| Example 3 | 36 | | 64 | | 25 | 0 | 75 | 0 | 1165 | 135 | 8.6 |
| Example 4 | 82 | | | 18 | 52 | 0 | 18 | 30 | 648 | 69 | 9.4 |
| Example 5 | 64 | | | 36 | 34 | 0 | 42 | 24 | 823 | 207 | 4.0 |
| Example 6 | 36 | | | 64 | 27 | 0 | 73 | 0 | 963 | 161 | 6.0 |
| Example 7 | 36 | 64 | | | 52 | 47 | 1 | 0 | 645 | 174 | 3.7 |
| Example 8 | 36 | 57 | | 7 | 41 | 32 | 14 | 13 | 735 | 185 | 4.0 |
| Example 9 | 36 | 48 | | 16 | 36 | 22 | 32 | 10 | 850 | 141 | 6.0 |
| Example 10 | 36 | 32 | | 32 | 30 | 4 | 66 | 0 | 913 | 152 | 6.0 |
| Comparative | 100 | | | | 100 | | | | 530 | 257 | 2.1 |
| Example 1 | | | | | | | | | | | |

(*) Thickness where OD is 3 at wavelength of 193 nm
(**) Just Etching Time

From the results in Table 1, it is understood that, as compared with the light shielding film of Comparative Example, the light shielding films of Examples each only require a shorter etching time although the thickness of each of them is equivalent to or greater than that of Comparative Example. Therefore, the etching time can be shortened.

The losing rate of each resist film formed on the light shielding film is 2.1 Å/sec and, therefore, the dry etching rate of each of the light shielding films of Examples 1 to 10 is faster. In other words, the selectivity to the resist exceeds 1.

In this manner, a pattern of the light shielding film was formed on each substrate by dry etching and then the remaining resist pattern was peeled off and removed by the use of hot concentrated sulfuric acid. Thus, a photomask was obtained.

For reference, spectral curves of the light shielding films of respective Examples are collectively shown in FIG. 3. The axis of abscissas represents wavelength and the axis of ordinates represents adsorption coefficient. It is shown that when the wavelength is, for example, equal to that of KrF excimer laser (248 nm) or longer, the adsorption coefficient is reduced. Therefore, in this wavelength range, the thickness of each film for obtaining the same optical density (e.g. 3.0) is expected to be increased.

### EXAMPLE 11

With respect to a photomask blank which was the same as that of Example 2, dry etching was performed in the same manner except that a mixed gas of Cl₂ and O₂ (Cl₂:O₂=20:1) was used as a dry etching gas after formation of a resist pattern.

As a result, although the etching time was equivalent to that in Example 2, the CD loss (CD error) (difference of a measured line width relative to a design line width) of a formed light shielding film pattern was 20 nm and thus was largely reduced as compared with a CD loss (CD error) of 80 nm of the pattern formed in Example 2. Namely, the CD linearity was improved. It is considered that this is because damage to the resist pattern was able to be reduced by a reduction in amount of oxygen in the dry etching gas.

### EXAMPLE 12

FIG. 4 is a sectional view showing a photomask blank according to Example 12 and photomask manufacturing processes using this photomask blank. As shown in the figure, (a), a photomask blank 30 of this Example comprises a halftone phase shifter film 4 on an optically transparent substrate 1 and a light shielding film 2 composed of a shielding layer 5 and a reflection preventing layer 6 on the halftone phase shifter film 4.

This photomask blank 30 can be manufactured by the following method.

By the use of a single wafer sputtering apparatus, reactive sputtering (DC sputtering) was carried out in a mixed gas atmosphere of argon (Ar) and nitrogen (N₂) (Ar:N₂=10 vol %:90 vol %) using a mixed target of molybdenum (Mo) and silicon (Si) (Mo:Si=8:92 mol %) as a sputtering target. Thus, on an optically transparent substrate made of quartz glass, a halftone phase shifter film for an ArF excimer laser (wavelength 193 nm) was formed in the form of a single layer containing molybdenum, silicon, and nitrogen as main components. This halftone phase shifter film exhibits a transmittance of 5.5% and a phase shift amount of about 180° at the wavelength of the ArF excimer laser (wavelength 193 nm).

Then, by the use of an in-line sputtering apparatus, reactive sputtering was carried out in a mixed gas atmosphere of argon and nitrogen (Ar:50 vol %, N₂:50 vol %) using a chromium target as a sputtering target and then reactive sputtering was carried out in argon and methane (Ar:89 vol %, CH₄:11 vol %). Thus, a shielding layer having a thickness of 39 nm was formed. Subsequently, reactive sputtering was carried out in a mixed atmosphere of argon and nitrogen monoxide (Ar:86 vol %, NO=3 vol %). Thus, a reflection preventing layer having a thickness of 7 nm was formed. Since the foregoing reactive sputtering using methane and the foregoing reactive sputtering using nitrogen monoxide were carried out in the same chamber, the atmosphere thereof became 100 vol % by Ar+N₂+NO. Herein, the shielding layer became a composition gradient film containing chromium, nitrogen, carbon, and oxygen which was used in the formation of the reflection preventing layer and slightly mixed into the shielding layer. Further, the reflection preventing layer became a composition gradient film containing chromium, nitrogen, oxygen, and carbon which was used in the formation of the shielding layer and slightly mixed into the reflection preventing layer. In this manner, a light shielding film composed of the shielding layer and the reflection preventing layer and having the total thickness of 46 nm was formed. The ratio of the thickness of the reflection preventing layer occupying in the total thickness of the light shielding film was 0.15. This light shielding film, as a stack structure in combination with the halftone phase shifter film, exhibited an optical density (O.D.) of 3.0. FIG. 5 shows a surface reflectance curve of the light shielding film. As shown in FIG. 5, the reflectance at the exposure wavelength of 193 nm was able to be suppressed to a low value of 13.5%. Further, with respect to the photomask defect inspection wavelengths of 257 nm and 364 nm, the reflectance became 19.9% and 19.7%, respectively, and were the values causing no problem in the inspection.

Then, an electron-beam resist film (CAR-FEP171 manufactured by Fuji Film Arch (FFA)) as a chemically amplified resist was formed on the photomask blank 30. The resist film was formed by spin coating by the use of a spinner (spin coating apparatus). After coating the resist film, a predetermined heated-air drying treatment was carried out by the use of a heated-air dryer.

Subsequently, required pattern writing was carried out with respect to the resist film formed on the photomask blank 30 by the use of an electron-beam writing apparatus and, thereafter, developing was carried out by the use of a predetermined developer to thereby form a resist pattern 7 (see FIG. 4, (b)).

Next, dry etching of the light shielding film 2 composed of the shielding layer 5 and the reflection preventing layer 6 was performed along the resist pattern 7 to thereby form a light shielding film pattern 2a (see the same figure, (c)). As a dry etching gas, use was made of a mixed gas of Cl₂ and O₂ (Cl₂:O₂=4:1). In this event, the just etching time was 129 seconds and the etching rate was 3.6 Å/sec given by light shielding film total thickness/etching time, which was very fast. Like in the foregoing Examples 1 to 10, the losing rate of the resist film was 2.1 Å/sec and resist losing rate:light shielding film dry etching rate=1:1.7. Thus, the selectivity of the light shielding film to the resist was 1.7. Since, in this manner, the selectivity of the light shielding film to the resist exceeded 1 (the etching rate of the light shielding film was faster than the losing rate of the resist and the light shielding film 2 had the thin thickness and further had the fast etching rate), the etching time was also short. Therefore, the sectional shape of the light shielding film pattern 2a became perpendicular and thus excellent. The resist film is left on the light shielding film pattern 2a.

Then, using the light shielding film pattern 2a and the resist pattern 7 as a mask, etching of the halftone phase shifter film 4 was carried out to thereby form a halftone phase shifter film pattern 4a (see the same figure, (d)). This etching of the halftone phase shifter film 4 is affected by the sectional shape of the light shielding film pattern 2a. Since the sectional shape of the light shielding film pattern 2a was excellent, the sectional shape of the halftone phase shifter film pattern 4a also became excellent.

Then, after peeling off (stripping off) the remaining resist pattern 7, a resist film 8 was again coated and, after performing pattern exposure for removing the unnecessary light shielding film pattern in the transfer region, the resist film 8 was developed to thereby form a resist pattern 8a (see the same figure, (e) and (f). Successively, wet etching was used to remove the unnecessary light shielding film pattern and the remaining resist pattern was peeled off. Thus, a photomask 40 was obtained (see the same figure, (g)).

In this Example, mainly nitrogen is contained in a large amount in the shielding layer 5 so as to increase the etching rate of the whole light shielding film 2. Carbon contained in the shielding layer 5 and the reflection preventing layer 6 is considered to provide an effect of reducing the reflectance, an effect of reducing the film stress, an effect of increasing the etching rate of wet etching in removing the unnecessary light shielding film pattern, and so on.

### EXAMPLE 13

In the foregoing Example 12, light shielding film patterns were formed by changing the thickness of an electron-beam resist as a chemically amplified resist to 300 nm, 250 nm, and 200 nm. By adopting the light shielding film of this invention, even when the light shielding film pattern is formed using the resist pattern on the light shielding film as the mask, the resist film can be left on the formed light shielding film pattern. Therefore, the pattern accuracy (CD accuracy) of the light shielding film can be made excellent. For evaluation of the CD linearity, a 1:1 line and space pattern (1:1 L/S) and a 1:1 contact hole pattern (1:1 C/H) were formed as mask patterns. The 1:1 L/S and the 1:1 C/H were evaluated in the form of a 400 nm L/S pattern and a 400 nm C/H pattern, respectively. As a result, evaluation of the CD shift amount with respect to the design size revealed that, in the case of the 1:1 L/S, the CD shift amount was 23 nm at 300 nm, the CD shift amount was 17 nm at 250 nm, and the CD shift amount was 12 nm at 200 nm. On the other hand, in the case of the 1:1 C/H, the CD shift amount was 23 nm at 300 nm, the CD shift amount was 21 nm at 250 nm, and the CD shift amount was 19 nm at 200 nm. As described above, it is understood that, in combination with the light shielding film of this invention, the thickness of the resist can be reduced and the CD linearity is largely improved. Further, in the case of the thickness of the resist being 200 nm, an 80 nm line and space pattern (80 nm L/S) and a 300 nm contact hole pattern (300 nm C/H) required by the semiconductor design rule 65 nm were accurately resolved and the sectional shapes thereof were also excellent. Accordingly, since the sectional shape of each light shielding film pattern was excellent, the sectional shape of each halftone phase shifter film pattern formed by using the light shielding film pattern as a mask was also excellent.

### EXAMPLE 14

In the foregoing Example 12, photomasks were produced by changing the ratio of the reflection preventing layer 6 occupying in the whole light shielding film 2 and the thickness of a resist film formed on the light shielding film 2 while maintaining the optical properties of the light shielding film 2.

With respect to two kinds of photomask blanks in which the ratios of the reflection preventing layers 6 occupying the whole light shielding films 2 (reflection preventing layer thickness/light shielding film thickness) were set to 0.45, 0.30, and 0.20, resist films having different thicknesses of 300 nm, 250 nm, and 200 nm were formed on the light shielding films 2. Then, when patterning each light shielding film by dry etching using the resist pattern as a mask, the resist film remaining on the light shielding film was observed.

As a result, it was found that when the ratio of the reflection preventing layer occupying in the whole light shielding film was 0.45, the minimum required thickness of the resist film was 250 nm in order to leave the resist film on a light shielding film pattern even after formation of the light shielding film pattern to thereby achieve pattern accuracy of the light shielding film required by the semiconductor design rule 65 nm node. On the other hand, when the ratio of the reflection preventing layer occupying in the whole light shielding film was 0.30 or 0.20, the resist film was left on a light shielding film pattern and pattern accuracy of the light shielding film required by the semiconductor design rule 65 nm node was able to be achieved even in the case of the thickness of the resist film being 200 nm.

It is considered that the reason why the required pattern accuracy was not achieved when the thickness of the resist film was 200 nm in the case where the ratio of the reflection preventing layer occupying in the whole light shielding film was 0.45 is that when carbon is contained in the reflection preventing layer, the dry etching rate tends to be reduced and, therefore, the etching time required for patterning the light shielding film is increased so that the loss of the resist film proceeded.

In the foregoing Examples 1 to 11, a reflection preventing layer having a reflection preventing function is not formed at a surface layer of the light shielding film. However, use may be made of a light shielding film provided with a reflection preventing layer at its surface layer by adjusting the content of oxygen or the like contained at the surface layer of the light shielding film.

### BRIEF DESCRIPTION OF THE DRAWINGS

FIG. 1 A sectional view showing one embodiment of a photomask blank of this invention.

FIG. 2 A sectional view showing photomask manufacturing processes using a photomask blank.

FIG. 3 A diagram showing spectral curves of light shielding films of respective Examples.

FIG. 4 A sectional view showing a photomask blank according to Example 12 and photomask manufacturing processes using this photomask blank.

FIG. 5A diagram showing a surface reflectance curve of a light shielding film of Example 12.

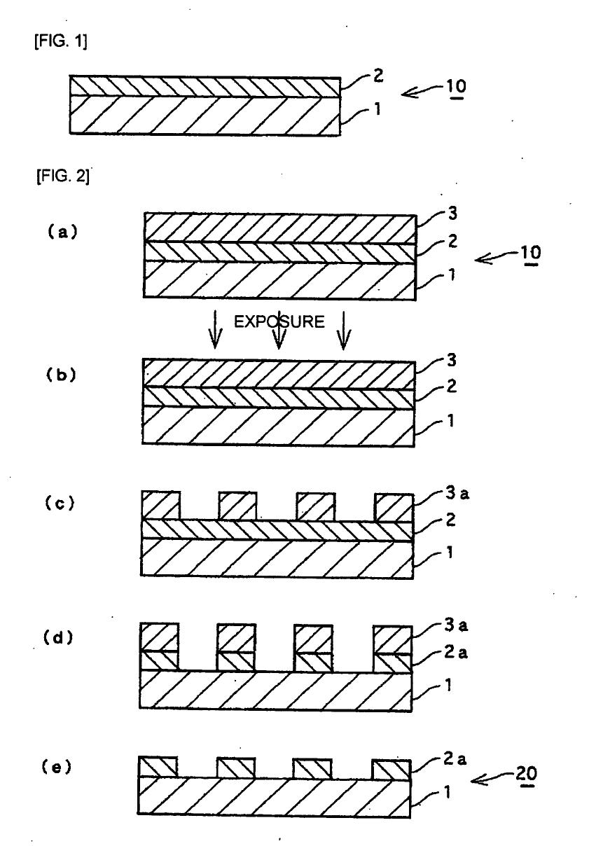

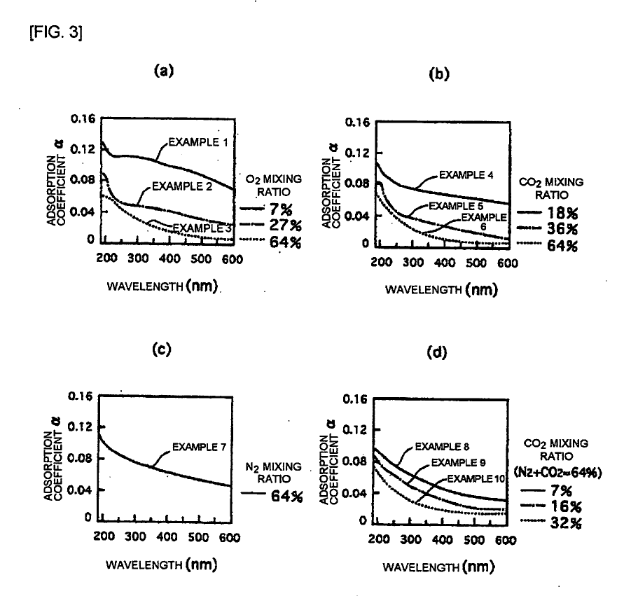

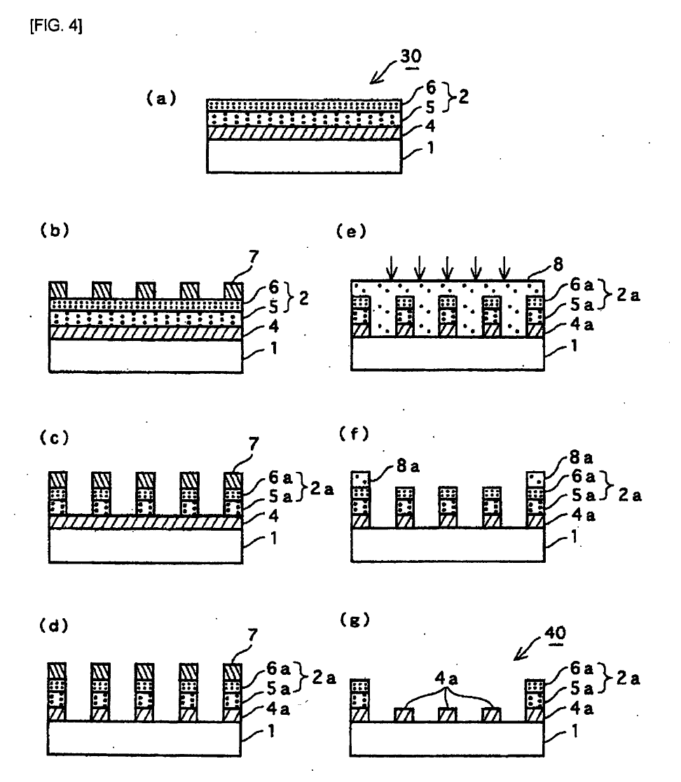

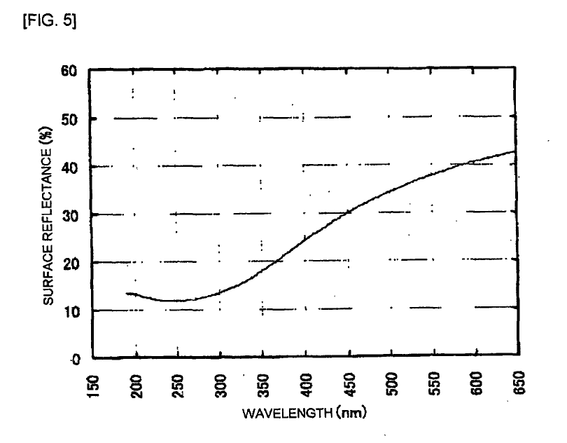

### DESCRIPTION OF SYMBOLS

1 optically transparent substrate
2 light shielding film
3 resist film
4 halftone phase shifter film
5 shielding layer
6 reflection preventing layer
2a light shielding film pattern
3a resist pattern
10, 30 photomask blank
20, 40 photomask

1. A photomask blank having a light shielding film on an optically transparent substrate, wherein:
the photomask blank is a mask blank for a dry etching process adapted for a photomask producing method of patterning the light shielding film by the dry etching process using as a mask a pattern of a resist formed on the light shielding film, and
the light shielding film is made of a material having a selectivity exceeding 1 with respect to the resist in the dry etching process.

2. A photomask blank having a light shielding film on an optically transparent substrate, wherein:
the photomask blank is a mask blank for a dry etching process adapted for a photomask producing method of patterning the light shielding film by the dry etching process using as a mask a pattern of a resist formed on the light shielding film, and
the light shielding film is made of a material of which an etching rate is faster than a losing rate of the resist in the dry etching process.

3. A photomask blank according to claim 1 or 2, wherein:
the resist film has a thickness of 300 nm or less.

4. A photomask blank having a light shielding film on an optically transparent substrate, wherein:
the photomask blank is a mask blank for a dry etching process adapted for a photomask producing method of patterning at least the light shielding film by the dry etching process using as a mask a pattern of a resist formed on the light shielding film, and
a dry etching rate of the light shielding film is set fast so that the resist remains on the light shielding film after patterning the light shielding film even when a thickness of the resist is set to 300 nm or less.

5. A photomask blank according to claim 1, 2 or 4, wherein:
the light shielding film is made of a material containing chromium.

6. A photomask blank according to claim 2 or 4, wherein:
an amount of an additional element causing the dry etching rate of the light shielding film to be faster than the losing rate of the resist is controlled.

7. A photomask blank having a light shielding film on an optically transparent substrate, wherein:
the photomask blank is a photomask blank for manufacturing a photomask for use in an exposure apparatus using exposure light having a wavelength of 200 nm or less as an exposure light source,
the light shielding film is made of a material containing chromium and an additional element that causes a dry etching rate to be faster than chromium alone, and
a thickness of the light shielding film is set so as to provide a required light shieldability.

8. A photomask blank according to claim 7, wherein:
the additional element contained in the light shielding film is an element being at least one of oxygen and nitrogen.

9. A photomask blank according to claim 1, 2, 4 or 7, comprising:
a reflection preventing layer containing oxygen at a top layer portion of the light shielding film.

10. A photomask blank according to claim 9, wherein:
the reflection preventing layer further contains carbon.

11. A photomask blank according to claim 9, wherein:
a ratio of the reflection preventing layer occupying in the whole of the light shielding film is set to 0.45 or less.

12. A photomask blank according to claim 1, 2, 4 or 7, wherein:
the dry etching process is performed in a plasma.

13. A photomask blank according to claim 1, 2, 4 or 7, wherein:
a dry etching gas for use in patterning the light shielding film is in the form of a chlorine-based gas or a mixed gas containing a chlorine-based gas and an oxygen gas.

14. A photomask blank according to claim 1, 2, 4 or 7, wherein:
the resist is a resist for electron-beam writing.

15. A photomask blank according to claim 1, 2, 4 or 7, wherein:
the resist is a chemically amplified resist.

16. A photomask blank according to claim 1, 2, 4 or 7, wherein:
a thickness of the light shielding film is set so that an optical density becomes 3.0 or more with respect to exposure light.

17. A photomask blank according to claim 16, wherein:
the thickness of the light shielding film is 90 nm or less.

18. A photomask blank according to claim 1, 2, 4 or 7, wherein:
a halftone phase shifter film is formed between the optically transparent substrate and the light shielding film.

19. A photomask blank according to claim 18, wherein:
the light shielding film is set such that a stack structure in combination with the halftone phase shifter film exhibits an optical density of 3.0 or more with respect to exposure light.

20. A photomask blank according to claim 19, wherein:
a thickness of the light shielding film is 50 nm or less.

21. A photomask manufacturing method comprising a step of patterning, by dry etching, the light shielding film in the photomask blank according to claim 1, 2, 4 or 7.

22. A photomask manufacturing method according to claim 21, comprising:
performing the dry etching under the conditions where when use is made, as the photomask blank, the photomask blank having the light shielding film made of the material containing at least oxygen in chromium and use is made, in the dry etching, the dry etching gas in the form of the mixed gas of the chlorine-based gas and the oxygen gas,
the content of oxygen in the dry etching gas being reduced depending on the content of oxygen contained in the light shielding film of the photomask blank.

23. A semiconductor device manufacturing method, comprising:
forming a circuit pattern on a semiconductor substrate by a photolithography method using a photomask obtained by the photomask manufacturing method according to claim 21.
